(19) United States
(12) Patent Application Publication
(10) Pub. No.: US 2023/0352911 A1
(43) Pub. Date: Nov. 2, 2023

(54) SEMICONDUCTOR OPTICAL DEVICE

(71) Applicant: Lumentum Japan, Inc., Sagamihara (JP)

(72) Inventors: Kazuki NISHIMURA, Tama (JP); Hideaki ASAKURA, Sagamihara (JP); Shunya YAMAUCHI, Sagamihara (JP); Ryosuke NAKAJIMA, Sagamihara (JP)

(21) Appl. No.: 17/821,308

(22) Filed: Aug. 22, 2022

(30) Foreign Application Priority Data
Apr. 27, 2022 (JP) 2022073132
Jun. 9, 2022 (JP) 2022093609

(51) Int. Cl. H01S 5/22; H01S 5/227; H01S 5/042; H01S 5/026

(52) U.S. Cl. CPC H01S 5/2228; H01S 5/2275; H01S 5/04256; H01S 5/04254; H01S 5/0265

(57) ABSTRACT

A semiconductor optical device includes: a semiconductor layer having a projection; a multiple quantum well layer on the projection; a pair of first semiconductor layers in contact with the mesa stripe structure on respective both sides; a pair of second semiconductor layers on the semiconductor layer; a pair of resin layers above the second semiconductor layers; a pair of third semiconductor layers on the second semiconductor layers, each third semiconductor layer surrounding a corresponding one of the resin layers, the third semiconductor layers being different in constituent material from the second semiconductor layers; a first electrode on the semiconductor layer; and a second electrode including a mesa electrode on the mesa stripe structure, a lead-out electrode extending in the second direction from the mesa electrode, and a pad electrode above one of the resin layers, the pad electrode being connected to the lead-out electrode.

### CROSS-REFERENCE TO RELATED APPLICATIONS

The present application claims priority to Japanese Patent Application 2022-073132 filed on Apr. 27, 2022 and to Japanese Patent Application 2022-093609 filed on Jun. 9, 2022, the contents of which are hereby incorporated by reference into this application.

### TECHNICAL FIELD

The present disclosure relates generally to a semiconductor optical device.

### BACKGROUND

A buried hetero-structure (BH structure) may be applied to an electro-absorption modulator (EA modulator). The BH structure is a structure in which a mesa stripe structure including an optical function layer is buried with a semiconductor layer (buried layer) to achieve high reliability and a high-speed response. Furthermore, parasitic capacitance can be reduced by forming a recess in the buried layer and embedding a resin with a low dielectric constant in the recess.

During a formation process, a depth control of the recess in the buried layer can be difficult. A variation in the depth of the recess causes a height fluctuation of a base under the resin, so the resin changes in thickness and other characteristics. In some cases, an etching stop layer stops etching, but the etching stop layer is also formed directly under the mesa stripe structure, thereby affecting electrical characteristics.

### SUMMARY

Some implementations described herein are directed to ensuring high reliability and reducing parasitic capacitance.

In some implementations, a semiconductor optical device includes: a semiconductor layer having a projection on an upper surface, the projection extending in one stripe shape in a first direction and constituting a bottom of a mesa stripe structure; a multiple quantum well layer extending in the first direction on the projection of the semiconductor layer and constituting another portion of the mesa stripe structure; a pair of first semiconductor layers in contact with the mesa stripe structure on respective both sides in a second direction perpendicular to the first direction; a pair of second semiconductor layers, on respective both sides of the projection in the second direction, on the upper surface of the semiconductor layer; a pair of resin layers above the pair of second semiconductor layers; a pair of third semiconductor layers on the pair of second semiconductor layers, each of the pair of third semiconductor layers surrounding a corresponding one of the pair of resin layers, the pair of third semiconductor layers being different in constituent material from the pair of second semiconductor layers; a first electrode on a lower surface of the semiconductor layer; and a second electrode including a mesa electrode on a top surface of the mesa stripe structure, the second electrode including a lead-out electrode extending in the second direction from the mesa electrode, the second electrode including a pad electrode above one of the pair of resin layers, the pad electrode being connected to the lead-out electrode.

### BRIEF DESCRIPTION OF THE DRAWINGS

FIG. 1 is a plan view of a semiconductor optical device according to a first example implementation.

FIG. 2 is a II-II cross-sectional view of the semiconductor optical device in FIG. 1.

FIG. 3 is a side view of the semiconductor optical device in FIG. 1.

FIG. 4 is a IV-IV cross-sectional view of the semiconductor optical device in FIG. 3.

FIG. 5 is a diagram of a manufacturing method of the semiconductor optical device according to the first example implementation.

FIG. 6 is a diagram of the manufacturing method of the semiconductor optical device according to the first example implementation.

FIG. 7 is a diagram of the manufacturing method of the semiconductor optical device according to the first example implementation.

FIG. 8 is a diagram of the manufacturing method of the semiconductor optical device according to the first example implementation.

FIG. 9 is a diagram of the manufacturing method of the semiconductor optical device according to the first example implementation.

FIG. 10 is a diagram of the manufacturing method of the semiconductor optical device according to the first example implementation.

FIG. 11 is a diagram of the manufacturing method of the semiconductor optical device according to the first example implementation.

FIG. 12 is a diagram of the manufacturing method of the semiconductor optical device according to the first example implementation.

FIG. 13 is a plan view of a semiconductor optical device according to a second example implementation.

FIG. 14 is a XIV-XIV cross-sectional view of the semiconductor optical device in FIG. 13.

FIG. 15 is a plan view of the semiconductor optical device according to a third example implementation.

FIG. 16 is a XVI-XVI cross-sectional view of the semiconductor optical device in FIG. 15.

FIG. 17 is a XVII-XVII cross-sectional view of the semiconductor optical device in FIG. 15.

### DETAILED DESCRIPTION

Some implementations are specifically described in detail in the following with reference to drawings. In the drawings, the same members are denoted by the same reference numerals and have the same or equivalent functions, and a repetitive description thereof may be omitted for the sake of simplicity. Note that, the drawings referred to in the following are only for illustrating the example implementations, and are not necessarily drawn to scale.

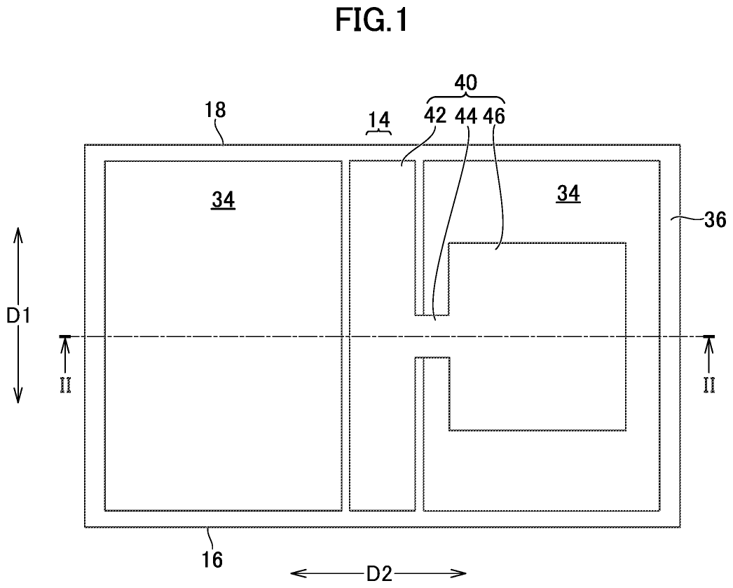

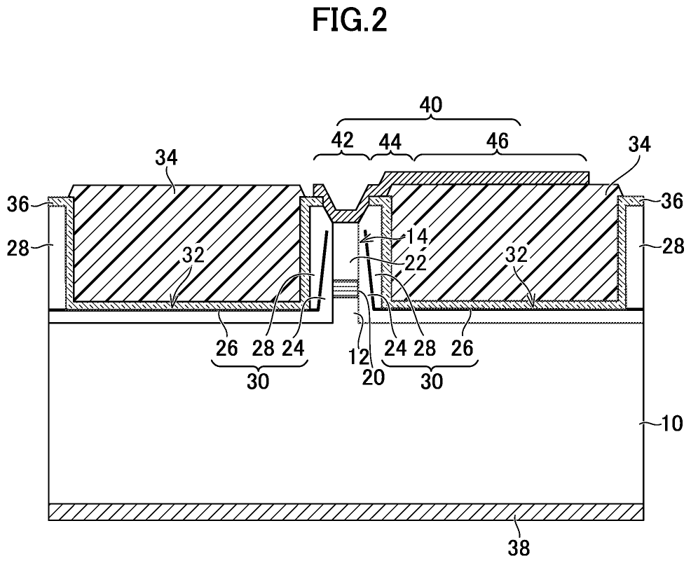

FIG. 1 is a plan view of a semiconductor optical device according to a first example implementation. FIG. 2 is a II-II cross-sectional view of the semiconductor optical device in FIG. 1. The semiconductor optical device may be an electro-absorption modulator (EA modulator), or may be a semiconductor laser, a light-receiving device, or another device.

The semiconductor optical device may have a semiconductor layer 10. The semiconductor layer 10 may be a semiconductor substrate (e.g., n-InP substrate) or a laminate with a buffer layer (e.g., n-InP layer) on the semiconductor substrate. The semiconductor layer 10 may have a projection 12 on an upper surface. The projection 12 may extend in one stripe shape in a first direction D1. The projection 12 may constitute a bottom of a mesa stripe structure 14. The mesa stripe structure 14 may extend from a rear-end surface 16 to a front-end surface 18 of the semiconductor optical device. The semiconductor layer 10 (particularly the projection 12) may serve as a lower clad layer of a first conductivity type (e.g., n-type).

The semiconductor optical device may have a multiple quantum well layer 20. The multiple quantum well layer 20 may be formed on the projection 12 of the semiconductor layer 10 extending in the first direction D1. The multiple quantum well layer 20 may constitute another portion of the mesa stripe structure 14. An upper surface (e.g., except for the projection 12) of the semiconductor layer 10 may be lower than a bottom edge of the multiple quantum well layer 20.

The semiconductor optical device may have an upper clad layer 22 of the second conductivity type (e.g., p-type). The upper clad layer 22 extends on the multiple quantum well layer 20 in one stripe shape in the first direction D1. The upper clad layer 22 may be a p-InP layer. Another layer (e.g., optical confinement layer) may be placed between the multiple quantum well layer 20 and the projection 12 (lower clad layer) or between the multiple quantum well layer 20 and the upper clad layer 22. In this example implementation, the first conductivity type may be the n-type and the second conductivity type may be the p-type, but vice versa may be possible. An unillustrated contact layer may be disposed on the upper clad layer 22.

The semiconductor optical device may have a pair of first semiconductor layers 24. The pair of first semiconductor layers 24 may be made of a semi-insulating semiconductor (e.g., Fe—InP). The pair of first semiconductor layers 24 may be in contact with the mesa stripe structure 14 (e.g., entire side surfaces) on respective both sides in a second direction D2 perpendicular to the first direction D1. The pair of first semiconductor layers 24 may be in contact with side surfaces of the projection 12 and extend to be also in contact with the upper surface (except for the projection 12) of the semiconductor layer 10.

The semiconductor optical device may have a pair of second semiconductor layers 26. The pair of second semiconductor layers 26 may be made of an intrinsic semiconductor (e.g., InGaAs) with no impurities intentionally added. The pair of second semiconductor layers 26 may be different in constituent material from the pair of first semiconductor layers 24. The pair of second semiconductor layers 26 may be, on respective both sides of the projection 12 in the second direction D2, on the upper surface of the semiconductor layer 10. The pair of first semiconductor layers 24 may extend below the respective pair of second semiconductor layers 26. The pair of second semiconductor layers 26 may completely cover the upper surface of the semiconductor layer 10, except near the top surface of the mesa stripe structure 14 (except for the projection 12). Furthermore, the second semiconductor layer 26 may be adjacent, in the second direction D2, to (in contact with) the first semiconductor layer 24, which may be adjacent to (in contact with) the mesa stripe structure 14.

The semiconductor optical device may have a pair of third semiconductor layers 28. The pair of third semiconductor layers 28 may be made of a semi-insulating semiconductor (e.g., Fe—InP). The pair of third semiconductor layers 28 may be the same in constituent material as the pair of first semiconductor layers 24. Each of the pair of third semiconductor layers 28 may be continuous to a corresponding one of the pair of first semiconductor layers 24. For example, the second semiconductor layer 26 may be continuous from a top of the first semiconductor layer 24, which rises along a side of the mesa stripe structure 14. Additionally, a corresponding one of the pair of second semiconductor layers 26 may be interposed between them.

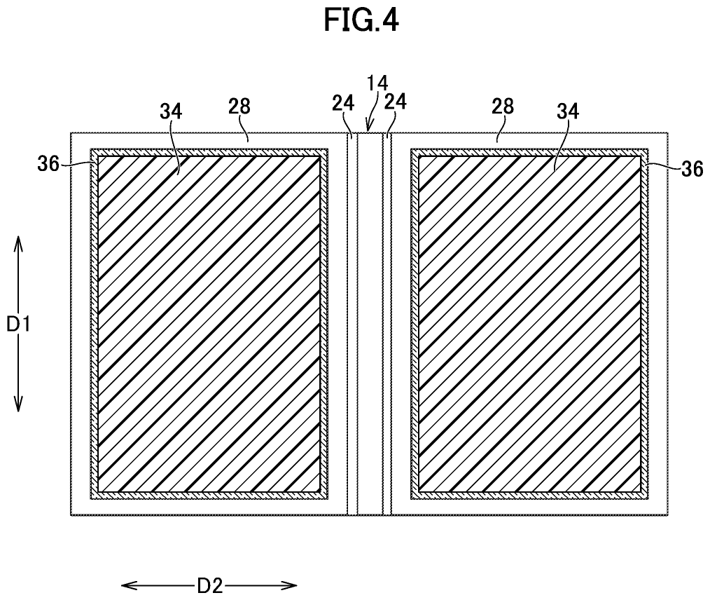

The pair of third semiconductor layers 28 may rise on the respective pair of second semiconductor layers 26. The pair of third semiconductor layers 28 may be different in constituent material from the pair of second semiconductor layers 26. Each of the pair of third semiconductor layers 28 may have a side surface exposed in at least one (e.g., both) of the first direction D1 and the second direction (see FIG. 4).

The pair of first semiconductor layers 24, the pair of second semiconductor layers 26, and the pair of third semiconductor layers 28 may constitute a buried layer 30 to the multiple quantum well layer 20. The buried layer 30 may be on both sides of the mesa stripe structure 14. The buried layer 30 may be provided except for the top surface of the mesa stripe structure 14. The buried layer 30 may be in contact with both side surfaces of the mesa stripe structure 14 on both sides in the second direction D2. The buried layer 30 may be higher than the mesa stripe structure 14. The buried layer 30 may extend from the rear-end surface 16 to the front-end surface 18.

The pair of second semiconductor layers 26 may extend horizontally along the upper surface (except for the projection 12) of semiconductor layer 10 but rise inclined, not vertically, next to the mesa stripe structure 14. This may be due to a sloping side surface of the first semiconductor layer 24. The buried layer 30 may have a pair of recesses 32. The recesses 32 may be on both sides of the mesa stripe structure 14. The recesses 32 may be surrounded with the buried layer 30 from all sides.

The semiconductor optical device may have a pair of resin layers 34. The pair of resin layers 34 may be disposed in the respective pair of recesses 32. The resin layers 34 may be arranged to fill the recesses 32. The resin layers 34 may comprise a material (e.g., benzocyclobutene (BCB), polyimide) having a lower dielectric constant than a semiconductor constituting the buried layer 30.

The semiconductor optical device may be obtained by forming multiple semiconductor optical devices in a semiconductor wafer and separating them into chips. The buried layer 30 (third semiconductor layer 28) may be cleaved (e.g., due to complexity associated with cutting the resin layer 34 when making the chips). Therefore, the resin layer 34 may not be exposed from end surfaces or side surfaces of the semiconductor optical device.

The pair of resin layers 34 may be above the respective pair of second semiconductor layers 26. Each of the pair of second semiconductor layers 26 extends between a corresponding one of the pair of first semiconductor layers 24 and a corresponding one of the pair of resin layers 34. The pair of resin layers 34 may be higher in height from the upper surface of the semiconductor layer 10 than the pair of first semiconductor layers 24. The resin layer 34 may be higher than the buried layer 30.

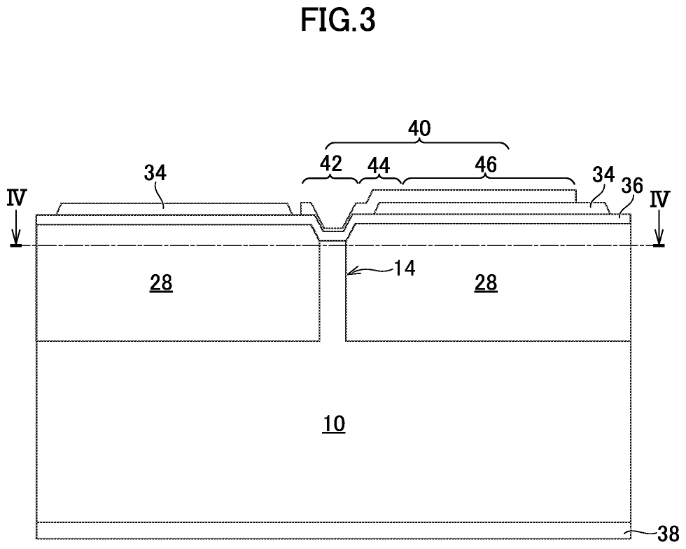

FIG. 3 is a side view, seen from the rear-end surface 16, of the semiconductor optical device in FIG. 1. FIG. 4 is a IV-IV cross-sectional view of the semiconductor optical device in FIG. 3. Each of the pair of third semiconductor layers 28 may surround a corresponding one of the pair of resin layers 34. Each of the pair of third semiconductor layers 28 may surround a corresponding one of the pair of resin layers 34 from one or more circumferential directions, such as the first direction D1 and the second direction D2.

Each of the pair of resin layers 34 may be surrounded with an inorganic insulating film 36 (e.g., silicon oxide film, silicon nitride film). The inorganic insulating film 36 may be interposed between each of the pair of resin layers 34 and a corresponding one of the pair of third semiconductor layers 28.

The inorganic insulating film 36 may be disposed along an inner surface of the recess 32. The inorganic insulating film 36 may be interposed between each of the pair of resin layers 34 and a corresponding one of the pair of first semiconductor layers 24. The inorganic insulating film 36 may be interposed between each of the pair of resin layers 34 and a corresponding one of the pair of second semiconductor layers 26. The inorganic insulating film 36 may be also disposed on a top edge of part (around the recess 32) of the buried layer 30 (FIG. 2). The inorganic insulating film 36 may not be disposed on a top surface of the mesa stripe structure 14.

The semiconductor optical device may have a first electrode 38 on the lower surface (back) of the semiconductor layer 10 (FIG. 2). The first electrode 38 may cover almost the entire lower surface of the semiconductor layer 10. The first electrode 38 may be electrically and physically connected to the semiconductor layer 10 and may be at the same potential as it. A semiconductor layer of the same conductivity type as the semiconductor layer 10 may be interposed between the first electrode 38 and the semiconductor layer 10.

The semiconductor optical device may have a second electrode 40. The entire second electrode 40 may be made of the same material and structure. The second electrode 40 may include a mesa electrode 42 on the top surface of the mesa stripe structure 14. The mesa electrode 42 may be electrically and physically connected to the mesa stripe structure 14. By applying a reverse-bias voltage between the mesa electrode 42 and the first electrode 38, the semiconductor optical device serves as a modulator that absorbs light in the multiple quantum well layer 20.

The mesa electrode 42 may have an elongated rectangular shape in a plan view. The mesa electrode 42 may have a tip, in the first direction D1, inside the rear-end surface 16 and the front-end surface 18 (FIG. 1), or may extend to the respective end surfaces. The mesa electrode 42 may have a small area to reduce parasitic capacitance (e.g., because large parasitic capacitance hinders high-speed drive). Therefore, when the mesa electrode 42 extends beyond the top surface of the mesa stripe structure 14 and onto the buried layer 30, the mesa electrode 42 may be narrow enough to be placed only on an edge adjacent to the mesa stripe structure 14. As shown in FIG. 1, the mesa electrode 42 does not overlap with the resin layer 34.

The second electrode 40 may include a lead-out electrode 44 extending from the mesa electrode 42 in the second direction D2. The lead-out electrode 44 may be narrower in width in the first direction D1 than the mesa electrode 42. Part of the lead-out electrode 44 may overlap with the resin layer 34. As shown in FIG. 1, only the end, adjacent to the mesa stripe structure 14, of the resin layer 34 may overlap with the lead-out electrode 44. The second electrode 40 may include a pad electrode 46, above one of the pair of resin layers 34, connected to the lead-out electrode 44. The pad electrode 46 may be wider in width in the first direction D1 than the lead-out electrode 44. The pad electrode 46 may be configured to be wire-bonded.

The semiconductor optical device may have at least two advantages. First, both sides of the mesa stripe structure 14 may be in contact with the semiconductor (buried layer 30). Therefore, compared to a structure in which a side of the mesa stripe structure 14 may be in contact with an inorganic material or a resin, semiconductors contained in the mesa stripe structure 14 may be prevented from being deteriorated, improving reliability.

Next, the recess 32 may be formed in the buried layer 30 and the resin layer 34 may be provided there, reducing the capacitance component and achieving an excellent high-speed response. Specifically, the resin layer 34 may be between the semiconductor layer 10 and combination of part of the lead-out electrode 44 and the pad electrode 46. Therefore, the parasitic capacitance caused by these electrodes may be reduced.

For example, assume a structure in which there is no recess 32 and the buried layer 30 is placed under the pad electrode 46. In this case, a parasitic capacitance is generated between the pad electrode 46 and the semiconductor layer 10. The parasitic capacitance depends on the distance between the pad electrode 46 and the semiconductor layer 10, the area of the pad electrode 46, and the dielectric constant of the layer between them. The semiconductor (buried layer 30) is between the pad electrode 46 and the semiconductor layer 10. Therefore, the dielectric constant of the buried layer 30 determines how large the parasitic capacitance is.

In this example implementation, there may be the resin layer 34 with a lower dielectric constant than the semiconductor (buried layer 30), between the pad electrode 46 and the semiconductor layer 10, whereby the parasitic capacitance may be reduced. Therefore, an excellent high-speed response may be achieved.

Furthermore, the resin layers 34 may be placed on both sides of the mesa stripe structure 14, whereby the capacitance may be reduced during high-frequency driving. When a high-frequency voltage is applied to the mesa stripe structure 14, the electric field spreads not only inside the mesa stripe structure 14 but also to both sides of it. Compared to a case where the buried layer 30 (semiconductor layer) is entirely provided on both sides of the mesa stripe structure 14, the resin layers 34 with the low dielectric constant enable the electric field distribution areas on both sides of the mesa stripe structure 14 to have a low dielectric constant. This contributes to faster operation. To obtain this effect, the thickness of the buried layer 30 to the side surface of the mesa stripe structure 14 may be 10 μm or less, or 5 μm or less to obtain a bandwidth enhancement effect of 10% or more compared to a case without the resin layer 34.

The pair of resin layers 34 may be located on both sides of the mesa stripe structure 14, therefore not only lowering the parasitic capacitance caused by the pad electrode 46 but also contributing to a lower capacitance of the electric field distribution areas that spreads to both sides of the mesa stripe structure 14. As a result, a semiconductor optical device with the excellent high-speed response can be provided.

Furthermore, the buried layer 30 may include the second semiconductor layers 26, whereby the recesses 32 may be straightforward to manufacture. As described in detail in a manufacturing method below, the second semiconductor layers 26 may be different in material from the first semiconductor layers 24 and the third semiconductor layers 28, serving as etching stop layers during formation of the recesses 32.

In this example implementation, the second semiconductor layers 26, which serve as the etching stop layers, may not be located below the mesa stripe structure 14. No layer with a different band gap may be included between the projection 12, below the multiple quantum well layer 20, and the semiconductor layer 10, therefore making no electrical effect.

Light guided around the multiple quantum well layer 20 may spread to the buried layer 30. If the second semiconductor layer 26 is close to the mesa stripe structure 14, it may cause an optical effect. Therefore, the second semiconductor layer 26 may be located 300 nm or more away from the side surface of the multiple quantum well layer 20. In addition, to minimize the effect on optical properties, while the second semiconductor layer 26 serves as the etching stop layer, the thickness of the second semiconductor layer 26 may be 5 nm or less.

The thicker the resin layer 34 is, the more it can reduce parasitic capacitance caused by the pad electrode 46. However, if the resin layer 34 rises from the buried layer 30 around the recess 32, a large step (height difference) may be created between the pad electrode 46 and the mesa electrode 42. As a result, an electrode discontinuity (step break) may occur at the lead-out electrode 44. Therefore, it may be desirable to make the recess 32 deeper for the resin layer 34 to be thicker and not to rise. The depth of the recess 32 may be determined by the location of the second semiconductor layer 26. One guideline may be to place the second semiconductor layers 26, on the upper surface (except for the projection 12) of the semiconductor layer 10, lower than the bottom edge of the multiple quantum well layer 20.

As described above, the semiconductor optical device can reduce the capacitance component without affecting optical and electrical characteristics while maintaining reliability, which is an advantage of the buried structure, whereby these contribute to faster operation.

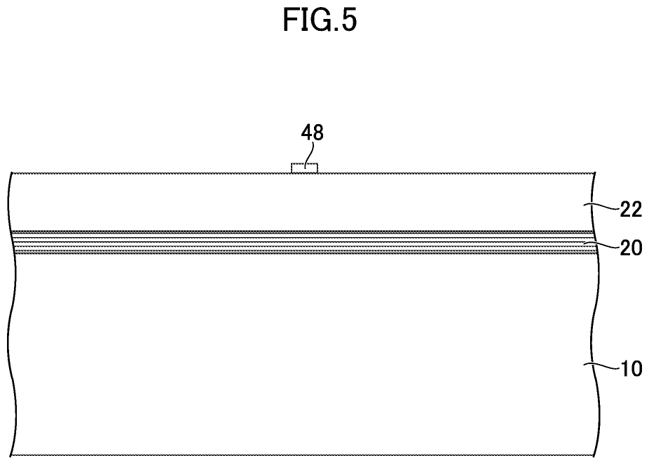

FIGS. 5 to 12 are diagrams of a manufacturing method of the semiconductor optical device according to the first example implementation. In this example implementation, the semiconductor layer 10 may be prepared in a wafer shape to perform manufacturing of multiple semiconductor optical devices.

As shown in FIG. 5, multiple semiconductor layers including the multiple quantum well layer 20 and the upper clad layer 22 may be formed on the semiconductor layer 10. The formation method may be MOCVD (Metal Organic Chemical Vapor Deposition) or any other formation method. An etching mask 48 may be formed to cover an area to be the mesa stripe structure 14.

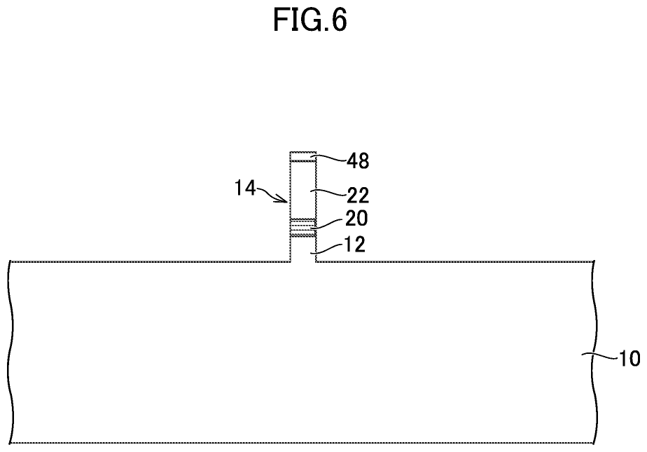

As shown in FIG. 6, an area not covered with the etching mask 48 may be etched to form the mesa stripe structure 14. Here, part of the semiconductor layer 10 may be also etched to form the projection 12.

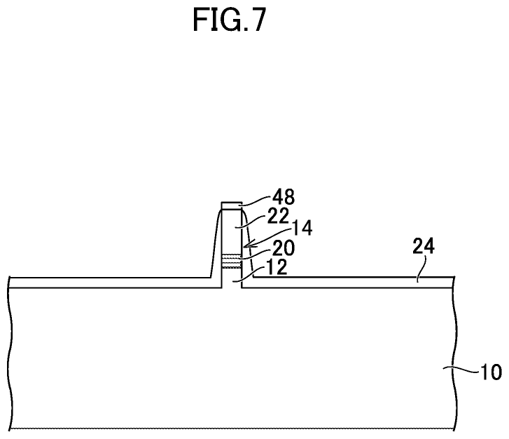

As shown in FIG. 7, the first semiconductor layers 24 may be formed, on the semiconductor layer 10, on both sides of the mesa stripe structure 14. The constituent material of the first semiconductor layers 24 may be InP. The formation method may be MOCVD method or any other formation method. The first semiconductor layers 24 may be formed on the upper surface of the semiconductor layer 10 and on the side surfaces of the mesa stripe structure 14. The side surfaces of the first semiconductor layers 24 rising along the mesa stripe structure 14 may be upwardly inclined to be close to the mesa stripe structure 14.

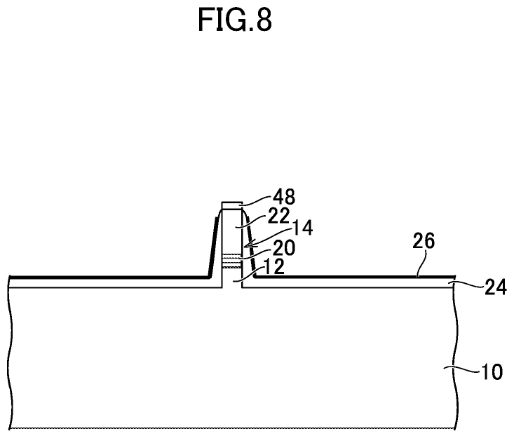

As shown in FIG. 8, the second semiconductor layers 26 may be formed on the first semiconductor layers 24. The constituent material of the second semiconductor layers 26 may be InGaAs. The formation method may be MOCVD method or any other method. The second semiconductor layers 26 may be formed along a surface profile of the first semiconductor layers 24. The second semiconductor layers 26, which may be very thin compared to the first semiconductor layers 24, may not extend to a vertex of the mesa stripe structure 14.

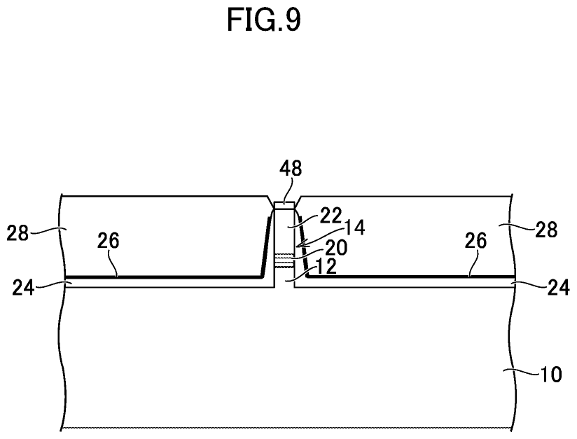

As shown in FIG. 9, the third semiconductor layers 28 may be formed on the second semiconductor layers 26. The constituent material of the third semiconductor layers 28 may be InP. The formation method may be MOCVD or any other method. Crystal growth may be performed until the third semiconductor layers 28 become higher than the mesa stripe structure 14, or it may be stopped at the same height as the mesa stripe structure 14.

The first semiconductor layer 24 and the third semiconductor layer 28 may be adjacent to and in contact with the top of the mesa stripe structure 14. Since both may be made of the same InP, their interface may not be clearly visible. Therefore, the interface between them may not be shown in FIG. 2, but in FIG. 9, the interface between them may be explanatorily illustrated.

The second semiconductor layers 26 may be adjacent to the top of the mesa stripe structure 14 and may completely cover the first semiconductor layers 24. In that case, the first semiconductor layers 24 may be not in contact with the third semiconductor layers 28, but there may be no impact on the characteristics of the semiconductor optical device. The etching mask 48 may then be removed.

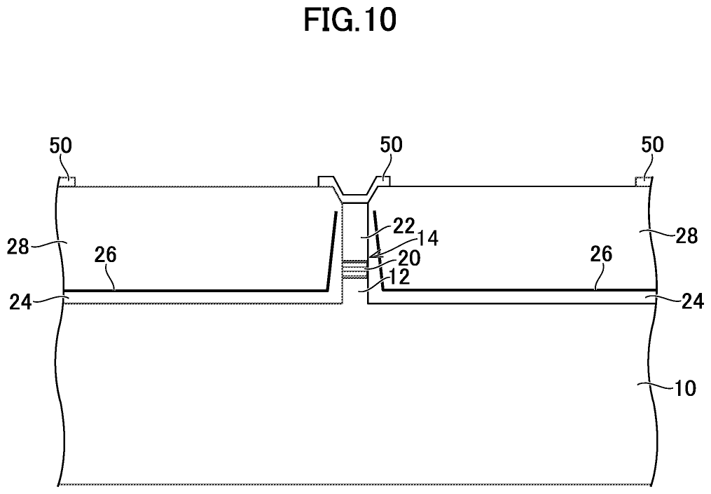

As shown in FIG. 10, an etching mask 50 may be formed. The etching mask 50 may cover the top surface of the mesa stripe structure 14 and the third semiconductor layers 28 except for areas that are to be the recesses 32.

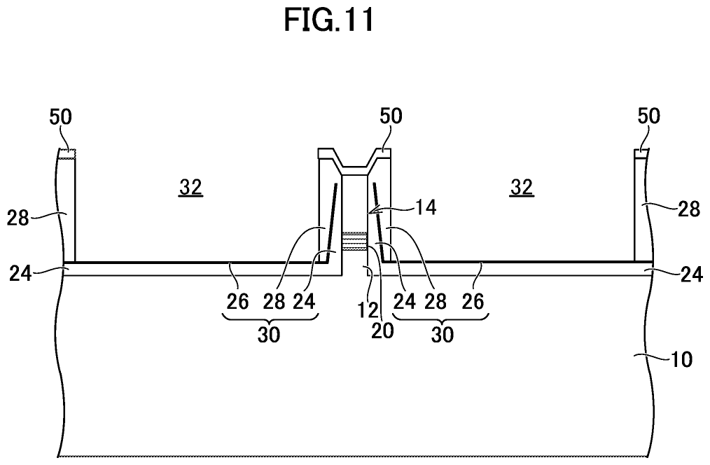

As shown in FIG. 11, part of the third semiconductor layers 28 may be removed by etching. The constituent material of the third semiconductor layers 28 may be InP. The constituent material of the second semiconductor layers 26 may be different from InP, so the etching may be stopped at surfaces of the second semiconductor layers 26 by using selective etching. The recesses 32 may be formed by the etching. The depth (bottom position) of the recesses 32 may be precisely to the surfaces of the second semiconductor layers 26. The material of the second semiconductor layers 26 may be InGaAs, InGaAsP, or InGaAsP. The etching mask 50 then may be removed.

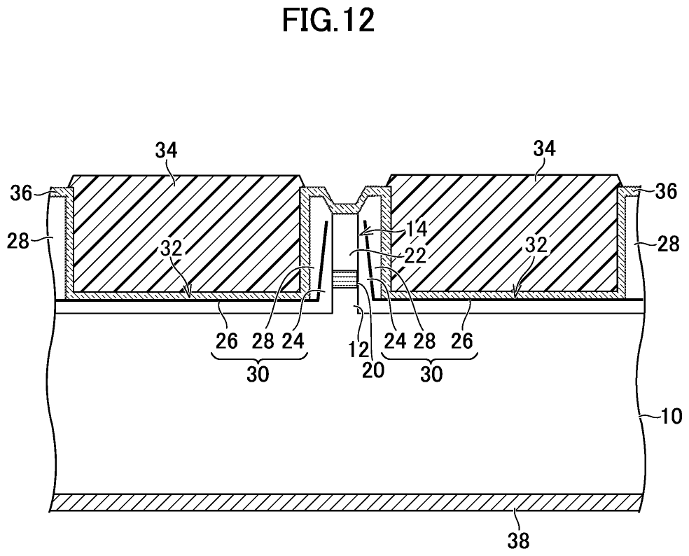

As shown in FIG. 12, the inorganic insulating film 36 may be formed on an entire surface including the recesses 32. The inorganic insulating film 36 may cover all of the top of the buried layer 30, the inner surfaces of the recesses 32, and the top surface of the mesa stripe structure 14. The resin layers 34 may be then formed in the recesses 32. The resin layers 34 may be formed to be higher than the inorganic insulating film 36.

The inorganic insulating film 36 may be removed on the top surface of the mesa stripe structure 14 (through-hole formation), and the second electrode 40 may be formed (see FIG. 2). The first electrode 38 may be formed on the lower surface (back) of the semiconductor layer 10. The semiconductor optical device may be then obtained through a process of cleaving the semiconductor wafer.

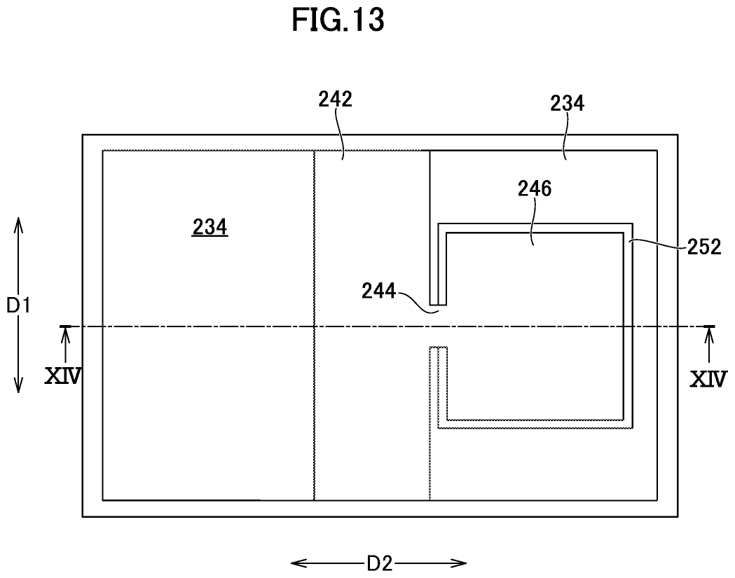

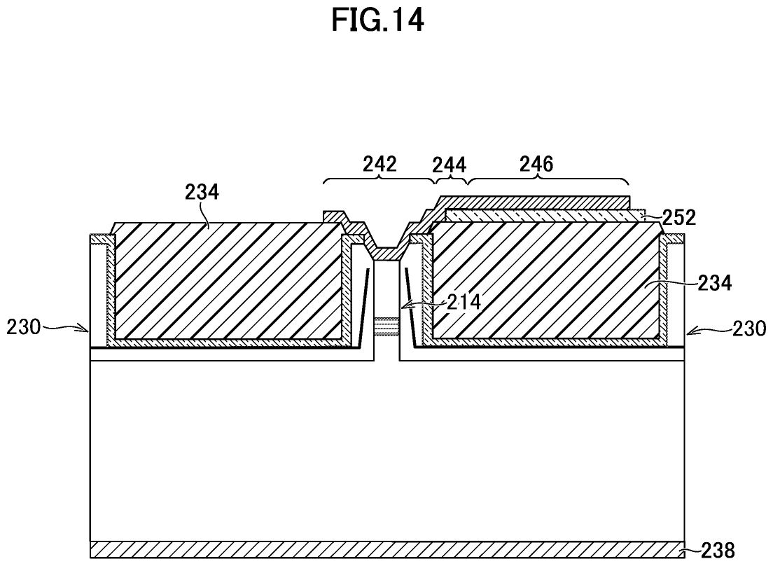

FIG. 13 is a plan view of a semiconductor optical device according to a second example implementation. FIG. 14 is a XIV-XIV cross-sectional view of the semiconductor optical device in FIG. 13.

The inorganic spacer 252 may be interposed between the pad electrode 246 and one of the pair of resin layers 234. The inorganic spacer 252 may be made of silicon nitride, for example, and may have a higher adhesion to the pad electrode 246 than the resin layers 234. The inorganic spacer 252 may keep the pad electrode 246 away from the first electrode 238, thereby having an effect of further reducing the parasitic capacitance caused by the pad electrode 246. The inorganic spacer 252 may be larger in planar shape than the pad electrode 246. The inorganic spacer 252 may overlap with part of the lead-out electrode 244.

The inorganic spacer 252 may have an end overlapping with the mesa electrode 242, or the end may extend to above the buried layer 230 adjacent to the mesa stripe structure 214. When the lead-out electrode 244 and part of the mesa electrode 242 overlap with the inorganic spacer 252, the parasitic capacitance caused by the electrodes in these areas may be reduced. Or, the inorganic spacer 252 may be smaller than the pad electrode 246, but the effect of reducing parasitic capacitance caused by pad electrode 246 may be smaller.

Part of the mesa electrode 242 may be on the pair of resin layers 234. This can reduce the parasitic capacitance caused by the mesa electrode 242. Compared to the first example implementation, the mesa electrode 242 may be large, so the parasitic capacitance may be large, but the tolerance against misalignment may be high and the manufacturability may be superior. The mesa electrode 242, when it is narrow, may be positioned out of the top surface of the mesa stripe structure 214 due to an effect from alignment accuracy of a photomask during manufacturing.

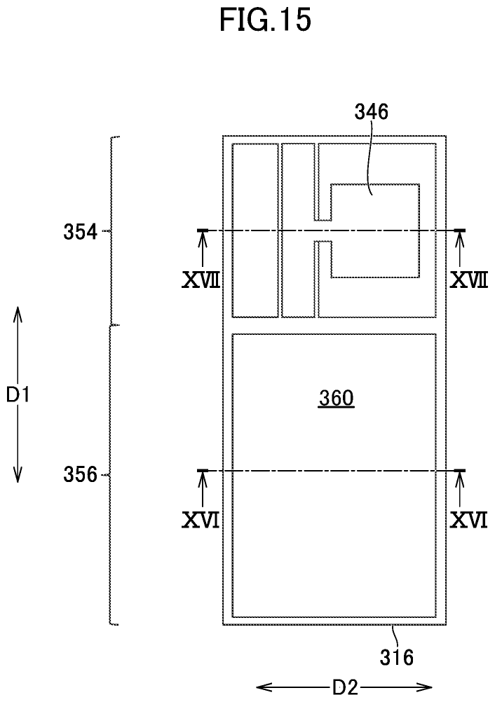

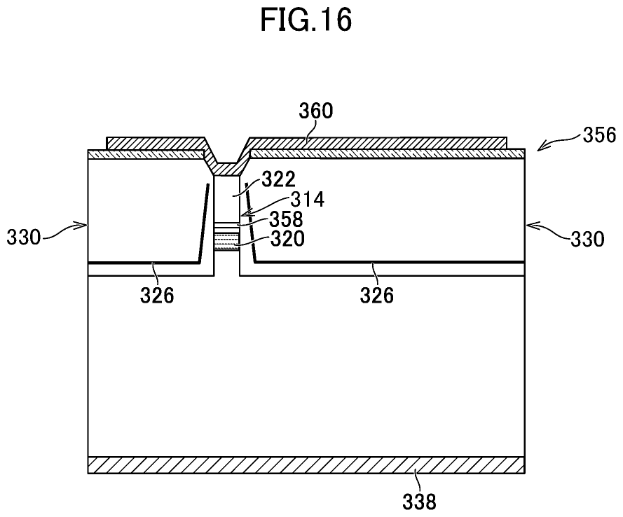

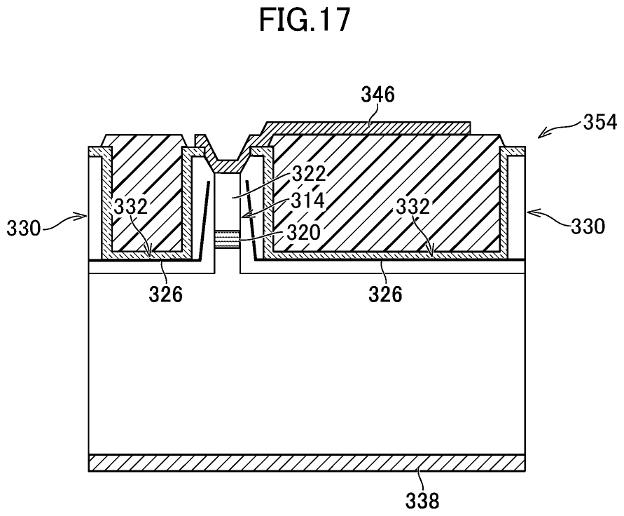

FIG. 15 is a plan view of the semiconductor optical device according to a third example implementation. FIG. 16 is a XVI-XVI cross-sectional view of the semiconductor optical device in FIG. 15. FIG. 17 is a XVII-XVII cross-sectional view of the semiconductor optical device in FIG. 15.

The semiconductor optical device may be a modulator-integrated semiconductor laser, which may include an EA modulator 354 and a semiconductor laser 356, and both may be monolithically integrated.

The semiconductor optical device may have the mesa stripe structure 314 running across both the semiconductor laser 356 and the EA modulator 354. The semiconductor laser 356 may include part of the mesa stripe structure 314. The semiconductor laser 356 may be configured to emit continuous light toward the EA modulator 354. An unillustrated dielectric high reflective film may be formed on the rear-end surface 316 of the semiconductor optical device, behind the semiconductor laser 356 (opposite to the EA modulator 354), while a low reflective film may be formed.

The semiconductor laser 356 may be any one of a DFB (Distributed Feedback) laser, FP (Fabry-Perot) laser, a DBR (Distributed Bragg Reflector) laser, or a DR (Distributed Reflector) laser, and may be configured to oscillate in a 1.3-μm bandwidth or 1.55-μm bandwidth. However, the wavelength range may not be limited to these, and another wavelength range may be utilized.

The semiconductor laser 356 may have the multiple quantum well layer 320 and a diffraction grating layer 358 on it. An upper clad layer 322 may be provided on the diffraction grating layer 358, and a clad layer may be also interposed between diffraction gratings. An unillustrated optical confinement layer may be provided above and below the multiple quantum well layer 320 and an unillustrated contact layer may be provided on the upper clad layer 322. The semiconductor laser 356 may have the laser electrode 360. By applying a voltage between the laser electrode 360 and the first electrode 338, the semiconductor laser 356 may oscillate continuous light.

The semiconductor laser 356 may have no recess in the buried layer 330. The parasitic capacitance may not be an issue because a direct current is injected into the semiconductor laser 356. Rather, from a viewpoint of heat dissipation, what may be next to the sides of the mesa stripe structure 314 should be entirely the buried layer 330. In some implementations, the second semiconductor layer 326 may be less than 5 nm, therefore having little effect on the functionality of the semiconductor laser 356.

The EA modulator 354 may include another portion of the mesa stripe structure 314. The mesa stripe structure 314 may be away from a center position of the semiconductor optical device in the second direction D2 to miniaturize the semiconductor optical device. The pad electrode 346 of the EA modulator 354 may require a certain area for wire bonding. One electrode may be sufficient for wire bonding, and a wide electrode may not be needed on the opposite side across the mesa stripe structure 314. Therefore, the semiconductor optical device may be downsized by reducing the area on the left side, compared to the first example implementation. Accordingly, more devices may be obtained from one semiconductor wafer, enabling cost reduction.

The structure of the semiconductor optical device in the second example implementation may be applied to the EA modulator 354 in the third example implementation. Other configurations may be the same as the semiconductor optical device in the first example implementation, except that the mesa stripe structure 314 may not be located at the center in the second direction D2.

In a first implementation, a semiconductor optical device includes: a semiconductor layer 10 having a projection 12 on an upper surface, the projection 12 extending in one stripe shape in a first direction D1 and constituting a bottom of a mesa stripe structure 14; a multiple quantum well layer 20 extending in the first direction D1 on the projection 12 of the semiconductor layer 10 and constituting another portion of the mesa stripe structure 14; a pair of first semiconductor layers 24 in contact with the mesa stripe structure 14 on respective both sides in a second direction D2 perpendicular to the first direction D1; a pair of second semiconductor layers 26, on respective both sides of the projection 12 in the second direction D2, on the upper surface of the semiconductor layer 10; a pair of resin layers 34 above the pair of second semiconductor layers 26; a pair of third semiconductor layers 28 on the pair of second semiconductor layers 26, each of the pair of third semiconductor layers 28 surrounding a corresponding one of the pair of resin layers 34, the pair of third semiconductor layers 28 being different in constituent material from the pair of second semiconductor layers 26; a first electrode 38 on a lower surface of the semiconductor layer 10; and a second electrode 40 including a mesa electrode 42 on a top surface of the mesa stripe structure 14, the second electrode 40 including a lead-out electrode 44 extending in the second direction D2 from the mesa electrode 42, the second electrode 40 including a pad electrode 46 above one of the pair of resin layers 34, the pad electrode 46 being connected to the lead-out electrode 44.

In addition to the pair of first semiconductor layers 24, the pair of second semiconductor layers 26, and the pair of third semiconductor layers 28, the pair of resin layers 34 can reduce parasitic capacitance. Furthermore, the pair of third semiconductor layers 28 are different in constituent material from the pair of second semiconductor layers 26. Therefore, it is easier to stop etching of the pair of third semiconductor layers 28 at the pair of second semiconductor layers 26 below it. This can suppress height variation of a base under the pair of resin layers 34, therefore ensuring high reliability.

In a second implementation, alone or in combination with the first implementation, the pair of first semiconductor layers 24, the pair of second semiconductor layers 26, and the pair of third semiconductor layers 28 constitute a buried layer 30 to the multiple quantum well layer 20, the buried layer 30 has a pair of recesses 32, and the pair of resin layers 34 are in the respective pair of recesses 32.

In a third implementation, alone or in combination with one or more of the first and second implementations, each of the pair of third semiconductor layers 28 surrounds the corresponding one of the pair of resin layers 34 from every circumferential direction including the first direction D1 and the second direction D2.

In a fourth implementation, alone or in combination with one or more of the first through third implementations, each of the pair of third semiconductor layers 28 may have a side surface exposed in at least one of the first direction D1 and the second direction D2.

In a fifth implementation, alone or in combination with one or more of the first through fourth implementations, the pair of first semiconductor layers 24 extend below the respective pair of second semiconductor layers 26 and in contact with the upper surface of the semiconductor layer 10.

In a sixth implementation, alone or in combination with one or more of the first through fifth implementations, each of the pair of second semiconductor layers 26 extends between a corresponding one of the pair of first semiconductor layers 24 and a corresponding one of the pair of resin layers 34.

In a seventh implementation, alone or in combination with one or more of the first through sixth implementations, the pair of first semiconductor layers 24 are different in the constituent material from the pair of second semiconductor layers 26.

In an eighth implementation, alone or in combination with one or more of the first through seventh implementations, the pair of third semiconductor layers 28 are the same in the constituent material as the pair of first semiconductor layers 24.

In a ninth implementation, alone or in combination with one or more of the first through eighth implementations, each of the pair of third semiconductor layers 28 is continuous to a corresponding one of the pair of first semiconductor layers 24.

In a tenth implementation, alone or in combination with one or more of the first through ninth implementations, the semiconductor optical device further including an inorganic insulating film 36 interposed between each of the pair of resin layers 34 and a corresponding one of the pair of second semiconductor layers 26.

In an eleventh implementation, alone or in combination with one or more of the first through tenth implementations, the inorganic insulating film 36 is also interposed between each of the pair of resin layers 34 and a corresponding one of the pair of first semiconductor layers 24.

In a twelfth implementation, alone or in combination with one or more of the first through eleventh implementations, the inorganic insulating film 36 is also interposed between each of the pair of resin layers 34 and a corresponding one of the pair of third semiconductor layers 28.

In a thirteenth implementation, alone or in combination with one or more of the first through twelfth implementations, the pair of first semiconductor layers 24 are made of a semi-insulating semiconductor.

In a fourteenth implementation, alone or in combination with one or more of the first through thirteenth implementations, the pair of second semiconductor layers 26 are made of an intrinsic semiconductor.

In a fifteenth implementation, alone or in combination with one or more of the first through fourteenth implementations, the semiconductor optical device further including an inorganic spacer 252 interposed between the pad electrode 246 and the one of the pair of resin layers 234.

In a sixteenth implementation, alone or in combination with one or more of the first through fifteenth implementations, the upper surface of the semiconductor layer 10, except for the projection 12, is lower than a bottom edge of the multiple quantum well layer 20.

In a seventeenth implementation, alone or in combination with one or more of the first through sixteenth implementations, part of the mesa electrode 242 is on the pair of resin layers 234.

In an eighteenth implementation, alone or in combination with one or more of the first through seventeenth implementations, the pair of resin layers 34 are higher in height from the upper surface of the semiconductor layer 10 than the pair of first semiconductor layers 24.

In a nineteenth implementation, alone or in combination with one or more of the first through eighteenth implementations, the semiconductor optical device is an electro-absorption modulator.

In a twentieth implementation, alone or in combination with one or more of the first through nineteenth implementations, the semiconductor optical device further including a semiconductor laser 356, wherein the semiconductor optical device is a modulator-integrated semiconductor laser in which the electro-absorption modulator 354 and the semiconductor laser 356 are monolithically integrated.

The example implementations described above are not limited and different variations are possible. The structures explained in the example implementations may be replaced with substantially the same structures and other structures that can achieve the same effect or the same objective.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor optical device comprising:
a semiconductor layer having a projection on an upper surface, the projection extending in one stripe shape in a first direction and constituting a bottom of a mesa stripe structure;
a multiple quantum well layer extending in the first direction on the projection of the semiconductor layer and constituting another portion of the mesa stripe structure;
a pair of first semiconductor layers in contact with the mesa stripe structure on respective both sides in a second direction perpendicular to the first direction;
a pair of second semiconductor layers, on respective both sides of the projection in the second direction, on the upper surface of the semiconductor layer;
a pair of resin layers above the pair of second semiconductor layers;
a pair of third semiconductor layers on the pair of second semiconductor layers, each of the pair of third semiconductor layers surrounding a corresponding one of the pair of resin layers, the pair of third semiconductor layers being different in constituent material from the pair of second semiconductor layers;
a first electrode on a lower surface of the semiconductor layer; and
a second electrode including a mesa electrode on a top surface of the mesa stripe structure, the second electrode including a lead-out electrode extending in the second direction from the mesa electrode, the second electrode including a pad electrode above one of the pair of resin layers, the pad electrode being connected to the lead-out electrode.

2. The semiconductor optical device according to claim 1, wherein
the pair of first semiconductor layers, the pair of second semiconductor layers, and the pair of third semiconductor layers constitute a buried layer to the multiple quantum well layer,
the buried layer has a pair of recesses, and
the pair of resin layers are in the respective pair of recesses.

3. The semiconductor optical device according to claim 1, wherein each of the pair of third semiconductor layers surrounds the corresponding one of the pair of resin layers from every circumferential direction including the first direction and the second direction.

4. The semiconductor optical device according to claim 1, wherein each of the pair of third semiconductor layers has a side surface exposed in at least one of the first direction and the second direction.

5. The semiconductor optical device according to claim 1, wherein the pair of first semiconductor layers extend below the respective pair of second semiconductor layers and in contact with the upper surface of the semiconductor layer.

6. The semiconductor optical device according to claim 1, wherein each of the pair of second semiconductor layers extends between a corresponding one of the pair of first semiconductor layers and a corresponding one of the pair of resin layers.

7. The semiconductor optical device according to claim 1, wherein the pair of first semiconductor layers are different in the constituent material from the pair of second semiconductor layers.

8. The semiconductor optical device according to claim 1, wherein the pair of third semiconductor layers are the same in the constituent material as the pair of first semiconductor layers.

9. The semiconductor optical device according to claim 8, wherein each of the pair of third semiconductor layers is continuous to a corresponding one of the pair of first semiconductor layers.

10. The semiconductor optical device according to claim 1, further comprising an inorganic insulating film interposed between each of the pair of resin layers and a corresponding one of the pair of second semiconductor layers.

11. The semiconductor optical device according to claim 10, wherein the inorganic insulating film is also interposed between each of the pair of resin layers and a corresponding one of the pair of first semiconductor layers.

12. The semiconductor optical device according to claim 10, wherein the inorganic insulating film is also interposed between each of the pair of resin layers and a corresponding one of the pair of third semiconductor layers.

13. The semiconductor optical device according to claim 1, wherein the pair of first semiconductor layers are made of a semi-insulating semiconductor.

14. The semiconductor optical device according to claim 1, wherein the pair of second semiconductor layers are made of an intrinsic semiconductor.

15. The semiconductor optical device according to claim 1, further comprising an inorganic spacer interposed between the pad electrode and the one of the pair of resin layers.

16. The semiconductor optical device according to claim 1, wherein the upper surface of the semiconductor layer, except for the projection, is lower than a bottom edge of the multiple quantum well layer.

17. The semiconductor optical device according to claim 1, wherein part of the mesa electrode is on the pair of resin layers.

18. The semiconductor optical device according to claim 1, wherein the pair of resin layers are higher in height from the upper surface of the semiconductor layer than the pair of first semiconductor layers.

19. The semiconductor optical device according to claim 1, wherein the semiconductor optical device is an electro-absorption modulator.

20. The semiconductor optical device according to claim 19, further comprising a semiconductor laser,
wherein the semiconductor optical device is a modulator-integrated semiconductor laser in which the electro-absorption modulator and the semiconductor laser are monolithically integrated.
